(19) United States
(12) Patent Application Publication
(10) Pub. No.: US 2018/0158714 A1
(43) Pub. Date: Jun. 7, 2018

(54) SUBSTRATE PROCESSING APPARATUS

(71) Applicant: HITACHI KOKUSAI ELECTRIC INC., Tokyo (JP)

(72) Inventors: Takashi YAHATA, Toyama-shi (JP); Tadashi TAKASAKI, Toyama-shi (JP)

(73) Assignee: HITACHI KOKUSAI ELECTRIC INC., Tokyo (JP)

(21) Appl. No.: 15/465,903

(22) Filed: Mar. 22, 2017

(30) Foreign Application Priority Data
Dec. 2, 2016 (JP) 2016-234952

(51) Int. Cl. H01L 21/687; H01L 21/67; C23C 16/455; C23C 16/458

(52) U.S. Cl. CPC H01L 21/68707; H01L 21/67201; H01L 21/67167; C23C 16/458; H01L 21/67126; C23C 16/455; H01L 21/67184

(57) ABSTRACT

A substrate processing apparatus and technique, capable of processing substrates regardless of the types of substrates, include a loadlock chamber accommodating a first support part and a second support part for supporting a wafer; a first transfer mechanism including first tweezers configured to transfer the substrate into or out of the loadlock chamber through a first side of the loadlock chamber; a second transfer mechanism including second tweezers configured to transfer the substrate into or out of the loadlock chamber through a second side of the loadlock chamber; and a reactor where the substrate is processed. The first support part includes first support mechanisms spaced apart by a first distance along a direction perpendicular to an entering direction of the first tweezers or the second tweezers, and the second support part includes second support mechanisms spaced apart by a second distance smaller than the first distance.

### CROSS-REFERENCE TO RELATED PATENT APPLICATION

This non-provisional U.S. patent application claims priority under 35 U.S.C. § 119 of Japanese Patent Application No. 2016-234952, filed on Dec. 2, 2016, the entire contents of which are hereby incorporated by reference.

### BACKGROUND

### 1. Field

The present disclosure relates to a substrate processing apparatus.

### 2. Description of the Related Art

A substrate processing apparatus including, for example a loadlock chamber, is used in a manufacturing process of a semiconductor device.

In the manufacturing process of semiconductor devices, various types of substrates having a diameter of 200 mm or 300 mm ate used. Conventionally, a substrate processing apparatus dedicated for either 200 mm substrate or 300 mm substrate has been developed.

With the recent growth of the Internet of Things (IoT) market, it is required to process various types of substrates. However, since the substrate processing apparatus has a large footprint or a high cost, having a substrate processing apparatus for each type of substrate is impractical.

### SUMMARY

Described herein is a technique for processing substrates regardless of the types of substrates.

According to one aspect, a technique is provided that includes a substrate processing apparatus, the substrate processing apparatus including: a loadlock chamber accommodating a first support part and a second support part configured to support a wafer, a first transfer mechanism including first tweezers configured to transfer the substrate into the loadlock chamber or transfer the substrate out of the loadlock chamber through a first side of the loadlock chamber; a second transfer mechanism including second tweezers configured to transfer the substrate into the loadlock chamber or transfer the substrate out of the loadlock chamber through a second side of the loadlock chamber; and a reactor where the substrate is processed, wherein the first support part includes first support mechanisms spaced apart by a first distance along a direction'perpendicular to an entering direction of the first tweezers or the second tweezers, and the second support part includes second support mechanisms spaced apart by a second distance smaller than the first distance.

### BRIEF DESCRIPTION OF THE DRAWINGS

FIG. 1 schematically illustrates a configuration of a substrate processing apparatus according to an embodiment described herein.

FIG. 2 schematically illustrates a configuration of the substrate processing apparatus according to the embodiment.

FIG. 3 schematically illustrates a configuration of a loadlock chamber of the substrate processing apparatus according to the embodiment.

FIG. 4 schematically illustrates the configuration of the loadlock chamber of the substrate processing apparatus according to the embodiment.

FIG. 5 schematically illustrates the configuration of the loadlock chamber of the substrate processing apparatus according to the embodiment.

FIG. 6 schematically illustrates a configuration of a reactor RC of the substrate processing apparatus according to the embodiment.

FIG. 7 schematically illustrates a configuration of a controller of the substrate processing apparatus according to the embodiment.

FIG. 8 is the flow chart illustrating a substrate processing using the substrate processing apparatus according to the embodiment.

FIG. 9 schematically illustrates the configuration of the loadlock chamber of the substrate processing apparatus according to the embodiment.

FIG. 10 schematically illustrates a configuration of a loadlock chamber according to a first comparative example.

FIG. 11 schematically illustrates a configuration of a loadlock chamber according to a second comparative example.

### DETAILED DESCRIPTION

Hereinafter, embodiments will be described with reference to the drawings.

### First Embodiment

Hereinafter, a first embodiment will be described.

The first embodiment will be described with reference to the drawings,

### Substrate Processing Apparatus

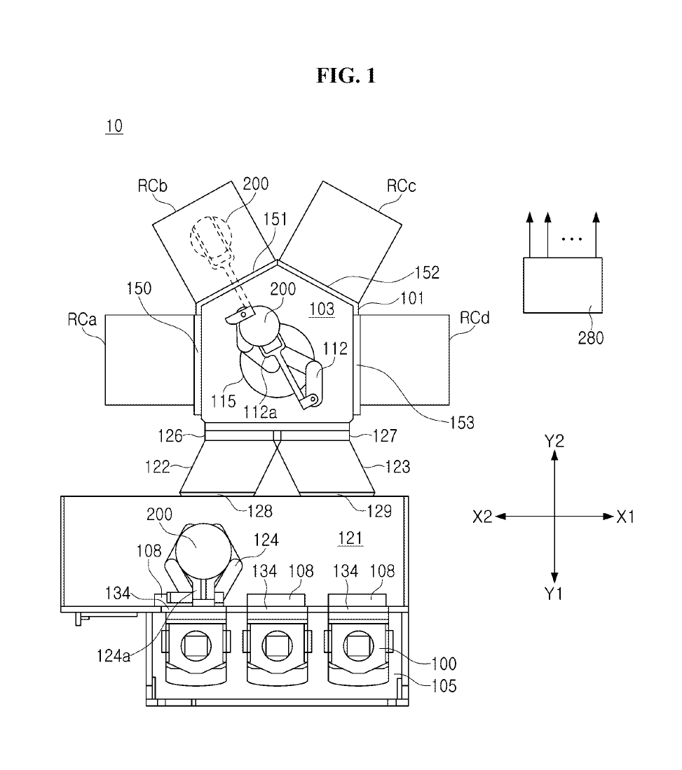

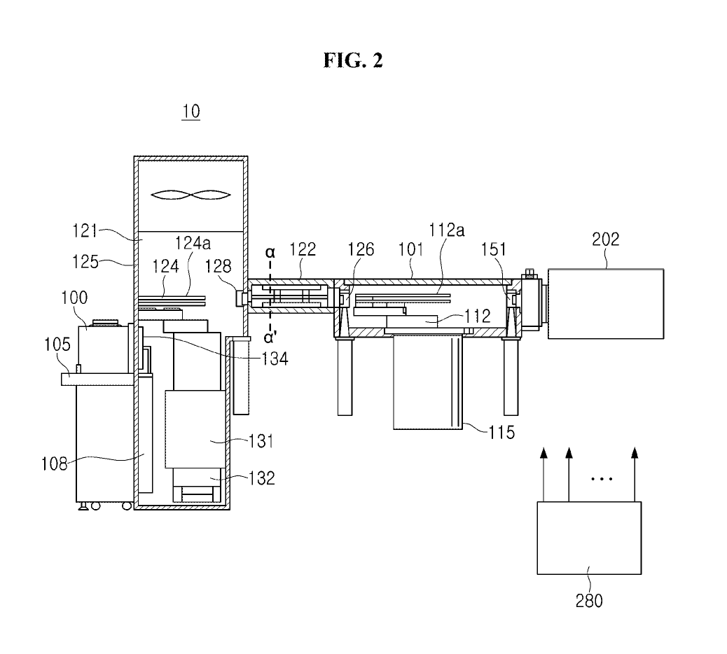

First, the substrate processing apparatus 10 according to the first embodiment will be described with reference to FIG. 1 and FIG. 2. FIG. 1 schematically illustrates a horizontal cross-section of a cluster type substrate processing apparatus 10 according to the first embodiment. FIG., 2 schematically illustrates a vertical cross-section of a cluster type substrate processing apparatus 10 according to the first embodiment.

In a substrate processing apparatus 10 according to the first embodiment, a FOUP (Front Opening Unified Pod, hereinafter referred to as “pod”) 100 is used as a carrier for transporting a wafer 200 as a substrate. The duster type substrate processing apparatus 10 according to the first embodiment is divided into a vacuum side and an atmospheric side.

Hereinafter, front, rear, left and right directions are indicated by arrow X₁, arrow X₂, arrow Y₁ and arrow Y₂ shown in FIG. 1, respectively.

### Configuration of Vacuum Side

As shown in FIG. 1 and FIG. 2, the substrate processing apparatus 10 includes a first transfer chamber 103 capable of withstanding negative pressure such as vacuum. The shape of a housing 101 of the first transfer chamber 103 is, for example, pentagonal when viewed from above. The housing 101 has closed, upper and lower ends.

In the first transfer chamber 103, a first wafer transfer device (first transfer mechanism) 112 configured to transfer the wafer 200 under negative pressure is installed. The first wafer transfer device 112 is moved up and down by the first wafer transfer device elevator 115 while the airtightness of the first transfer chamber 103 is maintained.

A loadlock chamber 122 and a loadlock chamber 123 are connected to one of the five sidewalls that is located on the front side, the pentagonal housing 101 via the gate valve 126 and the gate valve 127, respectively. The loadlock chamber 122 and the loadlock chamber 123 are capable to withstanding negative pressures, and devices for performing wafer loading and wafer unloading are installed therein. The detailed configurations of the loadlock chamber 122 and the loadlock chamber 123 will be described later.

A first reactor RCa, a second reactor RCb, a third reactor RCc and a fourth reactor RCd that perform predetermined processings on the substrate are connected adjacently to four sidewalls located on the rear side of the housing 101 of the first transfer chamber 103 with a gate valve 150, a gate valve 151, a gate valve 152 and a gate valve 153 interposed therebetween, respectively.

A second transfer chamber 121 wherein the wafer 200 are transported under vacuum and under atmospheric pressure is connected to the front sides of the loadlock chamber 122 and the loadlock chamber 123 via a gate valve 128 and a gate valve 129, respectively. A second wafer transfer device (second transfer mechanism) 124 transferring the wafer 200 is installed in the second transfer chamber 121. The second wafer transfer device 124 is moved up and down by a second wafer transfer device elevator 131 installed in the second transfer chamber 121 and is reciprocated laterally by a linear actuator 132.

A substrate loading/unloading port 134 and a pod opener 108 are installed at the front side of a housing 125 of the second transfer chamber 121 to load the wafer 200 into or unload the wafer 200 from the second transfer chamber 121. The loading port shelf 105 is installed at one side of the substrate loading/unloading port 134 opposite to where the pod opener 108 is installed, i.e. installed outside the housing 125.

The first wafer transfer device 112 includes first tweezers 112a that support the wafer 200. The first tweezers 112a may be exchanged depending on the type of substrate. For example, when the wafer 200 having a diameter of 300 mm is transferred, tweezers (first vacuum transfer tweezers) capable of handling vacuum and transporting 300 mm substrates may be used as the first tweezers 112a. When the wafer 200 having a diameter of 200 mm is transferred, tweezers (second vacuum transfer tweezers) capable of handling vacuum and transporting 200 mm substrates may be used as the first tweezers 112a. The second wafer transfer device 124 includes second tweezers 124a that support the wafer 200. The second tweezers 114a may be exchanged depending on the type of substrate. For example, when the wafer 200 having a diameter of 300 mm is transferred, tweezers (first atmospheric transfer tweezers) capable of handling atmospheric pressure and transporting 300 mm substrates may be used as the second tweezers 114a. When the wafer 200 having a diameter of 200 mm is transferred, tweezers (second atmospheric transfer tweezers) capable of handling atmospheric pressure and transporting 200 mm substrates may be used as the second tweezers 114a.

In the first embodiment, the wafer having a relatively large diameter is referred to as a wafer 200L, and the wafer having a relatively small diameter is referred to as a wafer 200S. For example, the wafer 200L may be a 300 mm substrate, and, the wafer 200S may be a 200 mm substrate.

### Loadlock Chamber

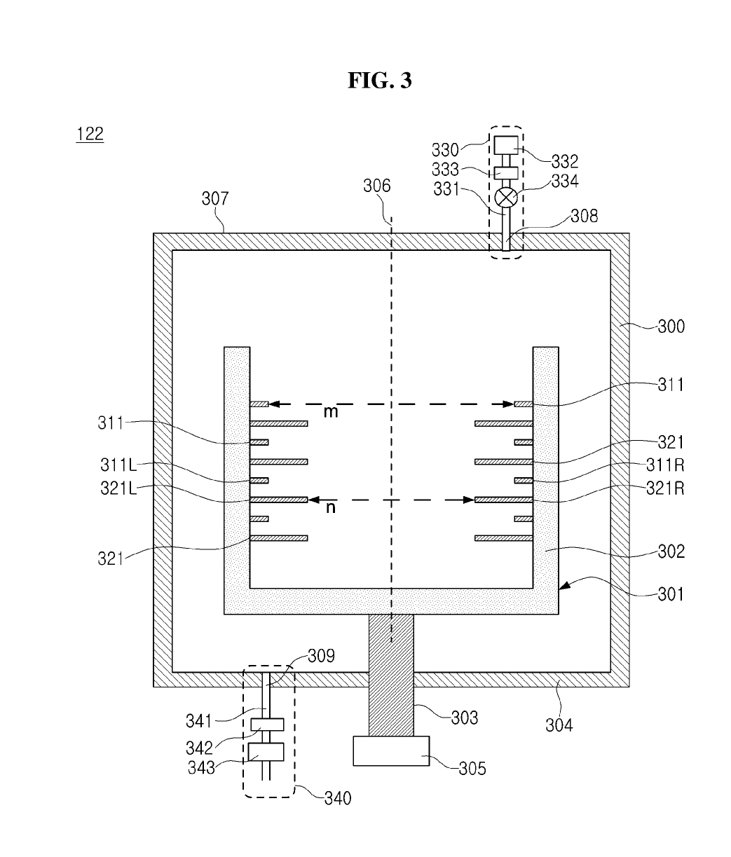

Next, the configurations of the loadlock chamber 122 and the loadlock chamber 123 according to the first embodiment will be described with reference to FIG. 3, FIG. 3 is a cross-sectional view of the substrate processing apparatus shown in FIG. 2 taken along the line α-α′. Hereinafter, the description will be focused on the loadlock chamber 122, and the description of the loadlock chamber 123 will be omitted. The tweezers 112a and the tweezers 124a move from the front side to the rear side or from the rear side to the front side.

The loadlock chamber 122 is defined by a housing 300. A loading/unloading port (not shown) is installed in the sidewall of the housing 300 adjacent to the housing 101 of the first transfer chamber 103 to transfer the wafer 200 from the first transfer chamber 103 to the loadlock chamber 122 or from the loadlock chamber 122 to the first transfer chamber 103. Similarly, a loading/unloading port (not shown) is installed in the sidewall of the housing 300 adjacent to the housing 125 of the second transfer chamber 121 to transfer the wafer 200 from the second transfer chamber 121 to the loadlock chamber 122 or from the loadlock chamber 122 to the second transfer chamber 121.

A boat 301, which is a substrate retainer, is installed in the housing 300. A first wafer support part (first support part) 311 and a second wafer support part (second support part) 321 are installed in the boat 301. A portion of the boat 301 toward the housing 101 and the housing 125 is open in order for the first tweezers 112a and the second tweezers 124a to enter along Y direction (denoted by the arrow Y₁ or the arrow Y₂ in FIG. 1). The boat 301 is supported by a boat support mechanism 303. The boat support mechanism 303 penetrates through a bottom 304 of the housing 300 and is supported by an elevating mechanism 305 to lift the boat 301.

The first wafer support part 311 includes a support mechanism (first support mechanism) 311 fixed to a sidewall 302 of the boat 301 in multiple stages. The support mechanism 311 includes a support mechanism 311R fixed to OM surface of the sidewall 302 of the boat 301 and a support mechanism 311L fixed to the other surface of the sidewall 302 of the boat 301.

The support mechanism 311L and the support mechanism 311R extend in the Y direction (denoted by the arrow Y₁ or the arrow Y₂ in FIG. 1). The support mechanism 311L and the support mechanism 311R extend from the sidewall 302 toward the center (denoted by broken line 306) of the housing 300 along X direction (denoted by the arrow X₁ or the arrow X₂ in FIG. 1). The support mechanism 311R and the support mechanism 311 L are spaced apart by first distance in. That is, the support mechanism 311R and the support mechanism 311L are separated by the first distance m along a direction perpendicular to the direction in which the first tweezers 112a or the second tweezers 124a enters the boat 301. The first distance m is greater than the width of the first vacuum transfer tweezers and the width of the first atmospheric transfer tweezers.

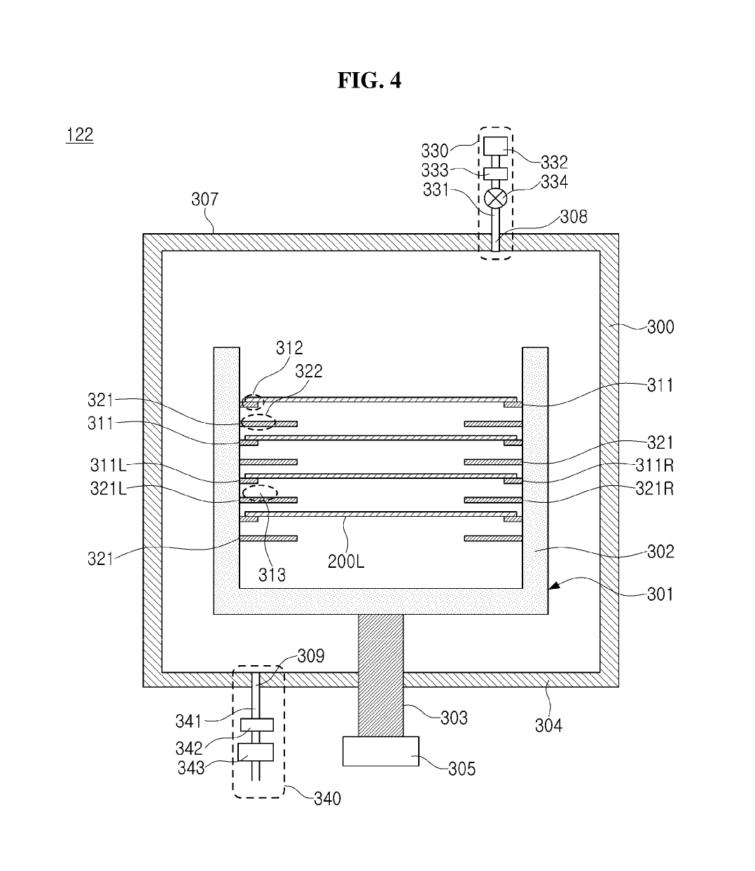

As shown in FIG. 4, the edge of the wafer 200L may be supported by the support mechanism 311R and the support mechanism 311L. For example, the wafer 200L shown in FIG. 4 is a 300 mm substrate.

The second wafer support part 321 includes a support mechanism 321L and a support mechanism 321R fixed to the sidewall 302 in multiple stages. The support mechanism 321R of the boat 301 is fixed to one surface of the sideman 302 of the boat 301 and the support mechanism 321L is fixed to the other surface of the sidewall 302 of the boat 301.

The support mechanisms 321L and 321R extend along the Y direction (denoted by the arrow Y₁ or the arrow Y₂ in FIG. 1). The support mechanisms 321L and 321R extend from the sidewall 302 toward the center (denoted by the Woken line 306) of the housing 300 along the X direction (denoted by the arrow X₁ or the arrow X₂ in FIG. 1). The support mechanism 321R and the support mechanism 321L are spaced apart by a second distance n. That is, the support mechanism 321R and the support mechanism 321L are separated by the second distance n along the direction perpendicular to the direction in which the first tweezers 112a or the second tweezers 124a enters the boat 301. The second distance n is greater than the width of the second vacuum transfer tweezers and the width of the second atmospheric transfer tweezers. The second distance is shorter than the first distance.

The support mechanisms 311L and 311R and the support mechanisms 321L and 321R are alternately arranged in the vertical direction.

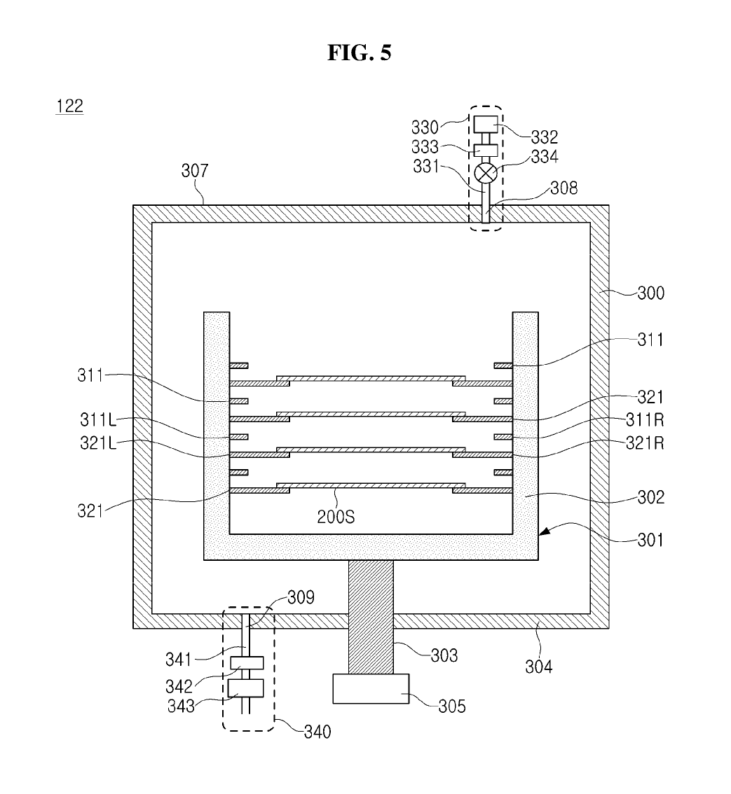

As shown in FIG. 5, the edge of the wafer 200S is supported by the support mechanism 321R and the support mechanism 321L.

An inert gas supply port 308 for supplying inert gas for adjusting the inner pressure of the housing 300 is installed at a ceiling 307 of the housing 300. An inert gas supply pipe 331 is connected to the inert gas supply port 308. An inert gas source 332, a mass flow controller 333 and a valve 334 are installed at the inert gas supply pipe 331 in order from the upstream side to the downstream side of the inert gas supply pipe 331 to adjust the amount of the inert gas supplied into the reaction vessel. A gas that does not affect the film formed on the wafer 200 is used as the inert gas. Rare gases such as helium (He) gas, nitrogen (N₂) gas and argon (Ar) gas can be used as an inert gas.

An inert gas supply unit 330 for supplying inert gas to the loadlock chamber 122 includes the inert gas supply pipe 331, the mass flow controller 333 and the valve 334. The inert gas supply unit 330 may further include the inert gas source 332 and the gas supply port 308.

An exhaust hole 309 is provided at the bottom 304 of the housing 300 to exhaust the inner atmosphere of the housing 300. An exhaust pipe 341 is connected to the exhaust hole 309. An APC 342, which is pressure controllers, and a pump 343 are installed at the exhaust pipe 341 in order from the upstream side to the downstream side of the exhaust pipe 341.

An gas exhaust unit 340, which exhausts the inner atmosphere of the loadlock chamber 122, includes the exhaust pipe 341 and the APC 342. The gas exhaust unit 340 may further include the pump 343 and the exhaust hole 309.

The inner atmosphere of the loadlock chamber 122 is co-controlled by the gas supply unit 330 and the gas exhaust unit 340.

Next, the advantages of alternately arranging the support mechanisms 311L and 311R and the support mechanisms 321L and 321R in a vertical direction are described.

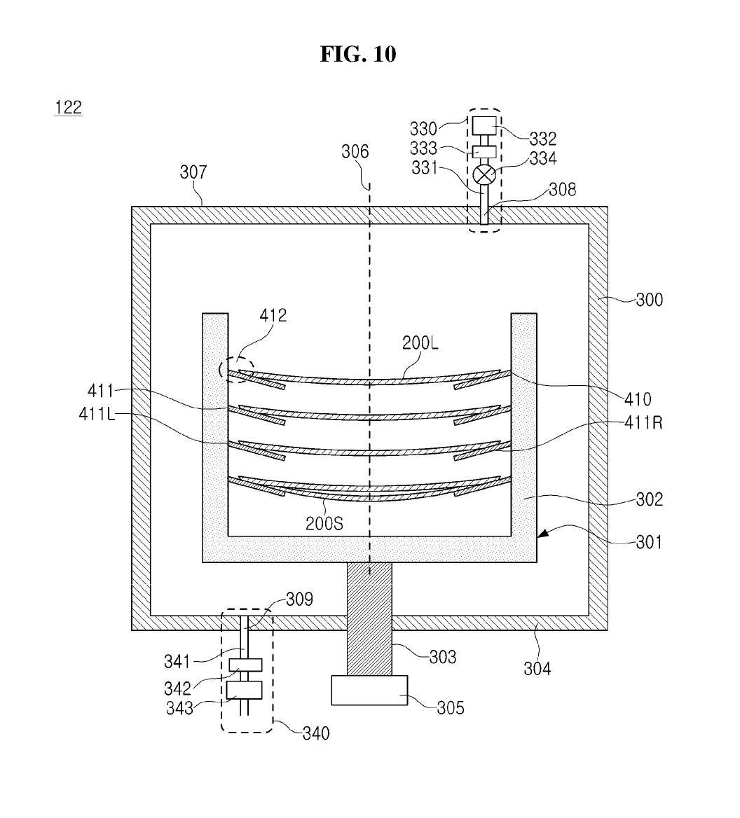

First, a first comparative example is described with reference to FIG. 10. Referring to FIG. 10, the wafer 200L and the wafer 200S are supported by the same support structure. For the purpose of description, both the wafer 200L and the wafer 200S are shown in FIG. 10.

According to the first comparative example shown FIG. 10, the wafer 200 is supported by a support part 410. The support part 410 includes a support mechanism 411. The support mechanism 411 includes a support mechanism 411R fixed to one surface of the sidewall 302 of the boat 301 and a support mechanism fixed to the other surface of the sidewall 302 of the boat 301

The support mechanism 411L and the support mechanism 411R extend obliquely downward from the sidewall 302. As shown in FIG. 10, the support mechanism 411L and the support mechanism 411R can support wafer 200L and wafer 200S. The wafer 200S may be supported by front end portions of the support mechanism 411L and the support mechanism 411R dose to the centerline 306. The wafer 200L may be supported by base portions 412 of the support mechanism 411L and the support mechanism 411R close to the sidewall 302.

According to the first comparative example shown in FIG. 10, the inventors of the present application found that when particles are produced at the base portion 412 of the support mechanism 411 in contact with the wafer 200L, the particles are diffused to the front end portion of the support mechanism 411 or to another support mechanism 411 below. When the wafer 200L is bent by the weight of the wafer 200L itself, the contact area between the support mechanism 411 and the wafer 200L at the base portion 412 increases. It is generally known that the amount of particles increases proportional to the contact area. As a result, the yield may be degraded.

As shown in FIG. 4, according to the first embodiment, since only the edge of the wafer 200L is supported, the contact area of the wafer 200L and the support mechanisms 311L and 311R does not increase even when the wafer 200L is bent. Therefore, the generation of particles or the degradation of yield may be prevented.

When particles are generated at the location 312, the particles may be captured at the base portion 322 of the support mechanisms 321L and 321R directly underneath. Therefore, the wafer 200L supported by the support mechanism 311 below the base portion 322 is not affected by the particles.

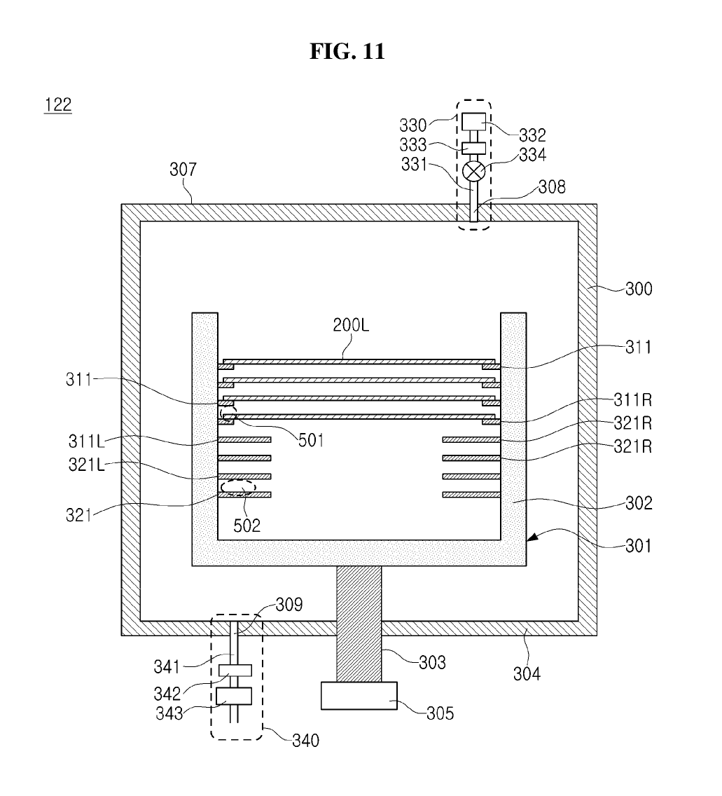

Next, a second comparative example is described with reference to FIG. 11. Referring to FIG. 11, the support mechanisms 311L and 311R for the wafer 200L and the support mechanisms 321L and 321R for the wafer 200S are not alternately arranged, but the support mechanisms 311L and 311R for the wafer 200L and the support mechanisms 321L and 321R for the wafer 200S are individually arranged in groups.

In FIG. 11, the reference numeral 501 represents the space between the support mechanisms 311 arranged in the vertical direction, and the reference numeral 502 represents the space between the support mechanisms 321 arranged in the vertical direction. The particles generated by contact with the wafer 200 stay in the space 501 and the space 502.

As described above, the inner atmosphere of the loadlock chamber 122 is alternately replaced pith a vacuum atmosphere and an atmospheric atmosphere. When the inner atmosphere of the loadlock chamber 122 is replaced, the inert gas is supplied and exhausted slowly and constantly by the cooperation of the gas supply unit 330 and the gas exhaust unit 340 to prevent the diffusion of the particles in the housing 300.

While it is facile to exhaust the inner atmosphere of the space 501, it is difficult to exhaust the inner atmosphere of the space 502 due to the long distance from the front end portions of the support mechanism 321L and 321R to the sidewall 302. In particular, when the inert gas is supplied and exhausted at a predetermined flow rate, it is difficult to exhaust the inner atmosphere of the space 502. In order to exhaust the inner atmosphere of the space 502, the amount of inert gas supplied and the amount of inert gas exhausted may be increased as well as increasing the flow rate of the inert gas. However, when a turbulent flow occurs due, to the inert gas colliding against the front ends of the support mechanisms 321L and 321R, the particles present in the space 501 or the space 502 may be diffused into the housing 300. The exhaust may be maintained until the inner atmosphere of the space 502 is evacuated While maintaining the flow rate of the inert gas at the predetermined flow rate. However, it takes a long time to substitute the atmosphere, thereby degrading the throughput.

As shown in FIG 4, according to the first embodiment, each structure is uniformly positioned and the upper portion of the space 313 between the support mechanisms 311L and 311R and the support mechanisms 321L and 321R is open. This structure facilitates the exhaust of the inner atmosphere around the location 312. Therefore, the particles can be easily exhausted without lowering the throughput.

When switching from the processing of the wafer 200L to the processing of the wafer 200S, it is possible for a maintenance personnel to manually clean the loadlock chamber 122 which does not affect by the particles present in other support mechanisms. However, since the structure of the loadlock chamber 122 is complex, at in particular, since the gap between the support mechanisms 311L and 311R and the support mechanisms 321L and 321R are small, the upper surfaces of the support mechanisms 311L and 311R and the support mechanisms 321L and 321R may not be sufficiently cleaned. Further, when cleaning is carried out frequently, the downtime increases, thereby deteriorating the processing efficiency. However, according to the first embodiment, the effects of particles are reduced and the downtime does not increase.

When the combination of the support mechanisms 311L and 311R and the support mechanisms 321L and 321R is employed, the support mechanisms 311L and 311R may be placed at the top. When the support mechanisms 321L and 321R are placed on top, the supplied inert gas first collides with the support mechanisms 321L and 321R, thereby causing turbulent flow. The generated turbulent flow diffuses the particles into the housing 300. When the support mechanisms 311L and 311R are placed at the top, the flow of the inert gas from the support mechanisms 311L and 311R to the support mechanisms 321L and 321R is not obstructed and a gas flow without turbulence may be formed. Therefore, the diffusion of the particles is suppressed.

### Reactor

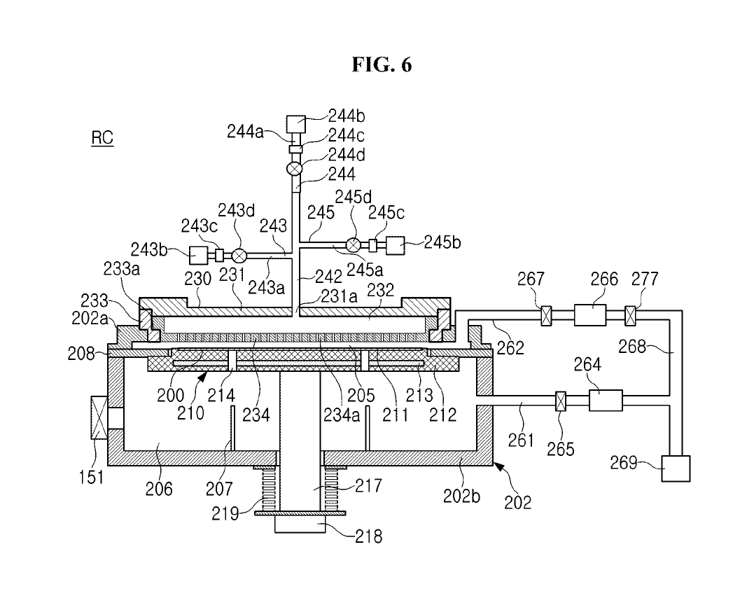

Next, the configuration of a reactor, which is a processing furnace that processes the substrate according to the first embodiment, is described with reference to FIG. 6. FIG. 6 schematically illustrates a vertical cross-section of the reactor in a substrate processing apparatus 10 according to the first embodiment.

In the first embodiment, a first reactor RCa, a second reactor RCb, a third reactor RCc and a fourth reactor RCd may be collectively referred to as “reactor RC”.

### Vessel

Referring to FIG. 6, reactor RC includes a vessel 202. A where processing space 205 where the wafer 200 such as a silicon wafer is processed, and a transfer space 206 through which the wafer 200 passes when the wafer 200 is transferred to the processing space 205 is provided in the vessel'202. The vessel 202 includes an upper vessel 202a and a lower vessel 202b. A partition plate 208 is installed between the upper vessel 202a and the lower vessel 202b.

A substrate loading/unloading port (not shown) is provided on the side surface of the lower vessel 202b adjacent to the gate valve 151. The wafer 200 is transferred between the housing 101 and the vessel 202 via the substrate loading/unloading port. Lift pins 207 are provided at the bottom of the lower vessel 202b. The lower vessel 202b is electrically grounded.

A substrate support part 210 which supports the wafer 200 is provided in the processing space 205. The substrate support part 210 includes a substrate support 212 having a substrate placing surface 211 on which the wafer 200 is placed and a heater 213 serving as a heat source provided in the substrate support 212. Through-holes 214 the lift pins 207 penetrate are provided at positions of the substrate support 212 corresponding to the lift pins 207.

The substrate support 212 is supported by a shall 217. The shaft 217 penetrates the bottom of the vessel 202 and is connected to an elevation unit 218 outside the vessel 202.

A shower head 230, which is a gas dispersion mechanism, is installed at the upstream side of the processing space 205. A gas introduction port 231a is installed in a cover 231 of the shower head 230. The gas introduction port 231a communicates with a common gas supply pipe 242 described later.

The shower head 230 has a dispersion plate 234 as a dispersion mechanism for dispersing the gas. A space at the upstream side of the dispersion plate 234 is referred to as a buffer space 232 and a space at the downstream side of the dispersion plate 234 is referred to as the processing space 205. The dispersion plate 234 is provided with a plurality of through-holes 234a.

The upper vessel 202a includes a flange (not shown). A support block 233 is placed on and fixed to the flange (not shown), The support block 233 includes a flange 233a. The dispersion plate 234 is placed on and fixed to the flange 233a. The cover 231 is fixed to the upper surface of the support block 233.

### Supply Units

The common gas supply pipe 242 is connected to the cover 231 to communicate with the, gas introduction port 231a provided in the cover 231 of the shower head 230. A first gas supply pipe 243a, a second gas supply pipe 244a, a third gas supply pipe 245a are connected to the common gas supply pipe 24.

### First Gas Supply System

A first gas source 243b, a mass flow controller (MFC) 243c which is a flow rate controller and an on/off valve 243d are installed at the first gas supply pipe 243a in sequence from the upstream side to the downstream side of the first gas supply pipe 243a.

The first gas source 243b is the source of a first gas containing a first element. The first gas containing the first element is also referred to as first element-containing gas. The first element-containing gas is one of source gases, i.e. process gases. In the first embodiment, the first element may include silicon (Si). That is, the first element-containing gas may include a silicon-containing gas. Specifically, hexachlorodisilane (Si₂Cl₆, also referred to as HCD) gas may be used as the silicon-containing gas.

The first gas supply system 243 (also referred to as a silicon-containing gas supply system) includes the first gas supply pipe 243a, the mass flow controller 243c and the valve 243d.

### Second Gas Supply System

A second gas source 244b, a mass flow controller (MFC) 244c which is a flow rate controller and an on/off valve 244d are installed at the second gas supply pipe 244a in sequence from the upstream side to the downstream side of the second gas supply pipe 244a.

The second gas source 244b is the source of a second gas containing a second element. The second gas containing the second element is also referred to as second element-containing gas. The second element-containing gas is one of the process gases. The second element-containing gas may act as a reactive gas or a modifying gas. The second element-containing gas may include oxygen (O₂) gas. The second element-containing gas may be used or processing the wafer 200L.

The second gas supply system 244 (also referred to as an oxygen-containing gas supply system) includes the second gas supply pipe 244a, the mass flow controller 244c and the valve 244d.

### Third Gas Supply System

A third gas source 245b, a mass flow controller (MFC) 245c which is a flow rate controller and an on/off valve 245d are installed at the third gas supply pipe 245a in sequence from the upstream side to the downstream side of the third gas supply pipe 245a.

The third gas source 245b is the source of a third gas containing a third element different from the second element. The third gas containing the third element is also referred to as third element-containing gas. The third element-containing gas is one of the process gases. The third element-containing gas may act as a reaction gas or a modifying gas. The third element-containing gas ma include ammonia (NH₃) gas. The third element-containing gas may be used for processing the wafer 200S.

The third gas supply system 245 includes the third gas supply pipe 245a, the mass flow controller 245c and the valve 245d.

### Exhaust System

The exhaust system for exhausting the inner, atmosphere of the vessel 202 includes a plurality of exhaust pipes connected to the vessel 202. The exhaust system includes an exhaust pipe (first exhaust pipe) 262 connected to the processing space 205 and an exhaust pipe (second exhaust pipe) 261 connected to the transfer space 206. An exhaust pipe (third exhaust pipe) 268 is connected to the downstream side of the exhaust pipes 261 and 262.

The exhaust pipe 261 is installed at the side or at the bottom of the transfer space 206. A pump (TMP) 264 is installed at the exhaust pipe 261. A valve 265, which is a first exhaust valve for the transfer space, is installed at the upstream side of the pump 264 installed at the exhaust pipe 261.

The exhaust pipe 262 is installed at one side of the processing space 205. An APC (Automatic Pressure Controller) 266, which is a pressure controller for adjusting the inner pressure of the processing space 205 to a predetermined pressure, is installed at the exhaust pipe 262. The APC 266 includes a valve body (not shown) capable of adjusting the opening degree thereof. The APC 266 adjusts the conductance of the exhaust pipe 262 in accordance with an instruction from the controller 280. A valve 267 is installed at the exhaust pipe 262 at the upstream side of the APC 266. The exhaust pipe 262, the valve 267 and the APC 266 may be collectively referred to as process chamber exhaust system.

A DP (Dry Pump) 269 is installed at the exhaust pipe 268. As shown in FIG. 6, the exhaust pipe 262 and the exhaust pipe 261 are connected to the exhaust pipe 268 in sequence from the upstream side to the downstream side of the exhaust pipe 268. The DP 269 is installed at the downstream side, of the portion of the exhaust pipe 268 to which the exhaust pipe 261 and the exhaust pipe 262 are connected. The DP 269 exhausts the inner atmosphere of the buffer space 232, the processing space 205 and the transfer space 206 via the exhaust pipe 262 and the exhaust pipe 261.

### Controller

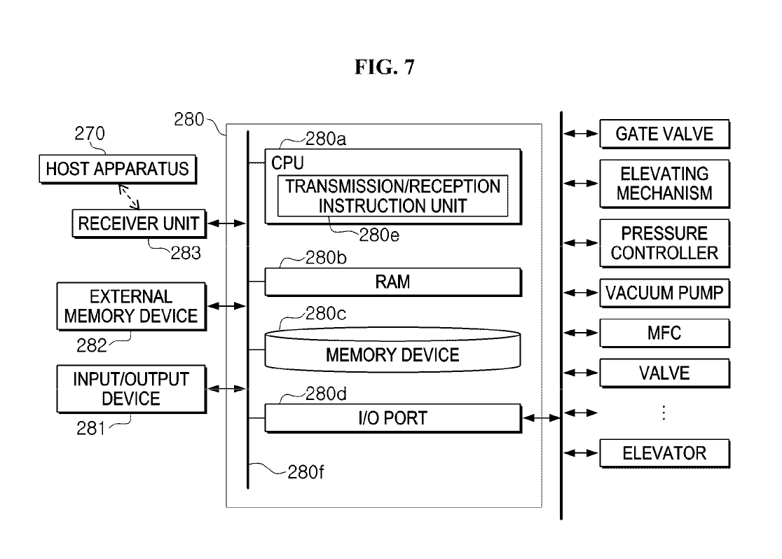

Next, the detailed configuration of the controller 280 will be described with reference to FIG. 7. The substrate processing apparatus 10 includes a controller 280 configured to controlling the operation of the components of the substrate processing apparatus 10.

The controller 280 which is a controller (control means) may be embodied as a computer including a central processing unit (CPU) 280a, a random access memory (RAM) 280b, a memory device 280c as a memory unit and an I/O port 280d . The RAM 280b, the memory device 280c and the I/O port 280d can exchange data with the CPU 280a via an internal bus 280f. The data can be exchanged (transmitted or received) in the substrate processing apparatus 10 in accordance with an instruction from the transmission reception instruction unit 280e, which is a function of the CPU 280a.

An external memory device 282 and an input/output device 281 such as a touch panel may be connected to the controller 280. The receiver unit 283 is connected to the controller 280. The receiver unit 283 is connected to a host apparatus (upper device) 270 via a network.

The memory de vice 280c is embodied by, for example, a flash memory or a hard disk drive (HDD). Data such as a control program for controlling the operation of the substrate processing apparatus, a process recipe storing sequences and conditions of substrate processing and a table described later are readably stored in the memory device 280c. The process recipe, when executed by the controller 280, functions as a program for performing each step of the substrate processing described below to obtain a predetermined result. Hereinafter, the process recipe and the control program are collectively referred to simply as program. The term “program” may refer to only the process recipe, only the control program, or both. The RAM 280b is a memory area (work area) in which programs or data read by the CPU 280a are temporarily stored.

The I/O port 280d is connected to the components of the substrate processing apparatus 10 such as the gate valve 151, the elevating mechanism 218 installed in the reactor RC, pressure controllers, pumps and elevators.

The CPU 280a reads and executes the control program from the memory device 280c and reads the process recipe from the memory device 280c in accordance with instruction such as an operation command inputted through the input/output device 28I. The CPU 280a controls the opening and closing operations of the gate valve 151, the operation of the wafer transfer devices 112 and 124, the operation of the elevating mechanism 218, the on/off control of the pump, flow rate adjustment operation of mass flow controller and opening and closing operation of a valve according to the process recipe. A plurality of process recipe may be stored to correspond to a plurality of wafers. For example, a first recipe for forming a silicon oxide film (SiO₂ film) on the wafer 200L and a second recipe for forming a silicon nitride film (SiN film) on the wafer 200S may be stored. For example, when the CPU 280a receives an instruction to process the wafer 200L or the wafer 200S from the component such as the host apparatus 270, the CPU 280a reads the first recipe or the second recipe.

In one embodiment, when the CPU 280a receives an instruction to load the wafer 200L into the reactor RC, the CPU 280a reads the first recipe. After the wafer 200L is placed on the first support mechanisms 311L and 311R and loaded into the reactor RC, the wafer 200L loaded into the reactor RC is processed according to the first recipe. For example, when the CPU 280a receives an instruction to load the wafer 200S into the reactor RC, the CPU 280a reads the second recipe. After the wafer 200S is placed on the second the support mechanisms 321L and 321R and loaded into the reactor RC, the wafer 200S loaded into the reactor RC is processed according to the second recipe.

The controller 280 may be embodied by installing the above-described program on a computer using the external memory device 282 storing the above-described program. The external memory device 282 may include a magnetic disk such as a hard disk, an optical disk such as a DVD, a magneto-optical disk such as MO and a semiconductor memory such as a USB memory. The method of providing the program to the computer is not limited to the external memory device 282. The program may be directly provided to the computer without using the external memory device 282 by a communication means such as the Internet and a dedicated line. The memory device 280c and the external memory device 282 are embodied by a computer-readable recording medium. Hereinafter, the memory device 280c and the external memory device 282 may be collectively referred to simply as a recording medium. As used herein, the term “recording medium” may refer to only the memory device 280c, only the external memory device 282, or both.

### Substrate Processing

Next, a process for forming a thin film on, the wafer 200 using the above-described substrate processing apparatus, which is one of the semiconductor manufacturing processes, will be described. In the following, the controller 280 controls the operations of the components constituting the substrate processing apparatus.

First, the processing of the wafer 200L is described. After the wafer 200L is placed in the first support part 311 of the loadlock chamber 122, the wafer 200L is transferred to the reactor RC. Thereafter, HCD gas obtained by vaporizing HCD, which is the first element-containing gas (first process gas), and O₂ gas, which is the second process gas (second process gas), are alternately supplied into the reactor RC A silicon oxide film (SiO film) is formed on the wafer 200L. An example of forming a silicon oxide film is described below in detail.

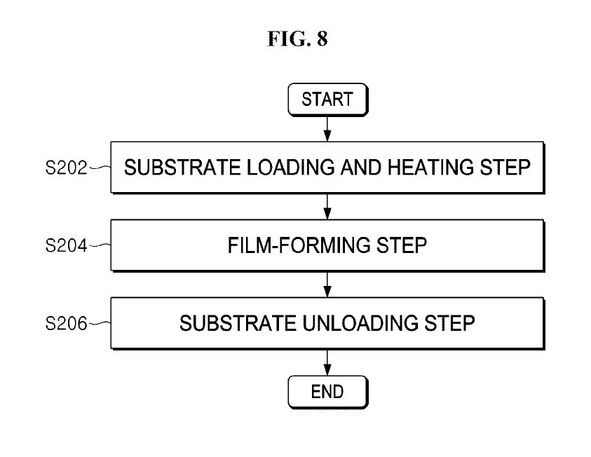

Next, the flow of forming a silicon oxide film will be described with reference to FIG. 8 in detail.

### Substrate Loading and Heating Step S202

When the wafer 200L is loaded into the vessel 202, the transfer device 112 is retracted to the outside of the vessel 202. By closing the gate valve 151, the vessel 202 is sealed. Thereafter, by elevating the substrate support 212, the wafer 200L is placed on the substrate placing surface 211 provided an the substrate support 212. By further elevating the substrate support 212, the wafer 200L is elevated to the substrate processing position in the processing space 205.

After the wafer 200 is loaded into the transfer space 206 and elevated to the processing position in the processing space 205, the valve 265 is closed. Thus, the transfer space 206 is isolated from the TMP 264 and the exhaust of the transfer space 205, which is performed by the TMP 264, is terminated. By opening the valve 267 and valve 277, the processing space 205 communicates with the APC 266 and the APC 266 communicates with the OP 269, respectively, The APC 266 adjusts the conductance of the exhaust pipe 262 to control the flow rate of the inner atmosphere of the processing space 205 exhausted by the DP 269. As a result, the pressure of the processing space 205 is maintained at a predetermined pressure (for example, a high vacuum of 10⁻⁵ Pa to 10⁻¹ Pa).

In the substrate loading and heating step S202, the inner pressure of the processing space 205 is adjusted to the predetermined pressure, and the temperature of the surface of the wafer 200L is adjusted to a predetermined temperature. The temperature of the surface of the wafer 200L ranges, for example, from room temperature to 500° C., preferably from room temperature to 400° C. The inner pressure of the processing space 205 ranges, for example, from 50 Pa to 5000 Pa.

### Film-Forming Step S204

After performing the substrate loading and heating step S202, a film-forming step S204 is performed. The film-forming step is performed by supplying the first gas into the, processing. space 205 by controlling the first gas supply system 243 according to the process recipe and exhausting the processing space 205 by controlling the exhaust system. In the film-forming step S204, by controlling the second gas supply system 244, the second gas may be supplied into in the processing space 205 simultaneously with the first gas to perform a CVD process. Alternately, the first gas and the second gas may be alternately supplied by controlling the first gas supply system 243 and the second gas supply system 244 to perform a cyclic process.

### Substrate Unloading Step S206

In the substrate unloading step S206, the processed wafer 200L is unloaded from the vessel 202. Next, an unprocessed wafer 200 may be loaded into the vessel 202 and then heated as the step S202. Then, the film-forming step S204 is performed on the loaded wafer 200,

Next, an example of the processing of the wafer 200S will be described. First, components such as tweezers are exchanged in the processing of the wafer 200S. Accordingly, the wafer 200S may be processed using the substrate processing apparatus described above. When the substrate processing apparatus is ready to process the wafer 200S, the wafer 200S is placed on the second support part 321 in the loadlock chamber 122, and the wafer 200S is transferred to the reactor RC. Thereafter, HCD gas obtained by vaporizing HCD which is the first element-containing gas (first process gas) and NH₃ gas (third process gas) are alternately supplied to forma silicon nitride film (SiN film), which is a silicon-containing film, is formed on the wafer 200S. The detailed process of forming the silicon nitride film (SiN film) is similar to that of forming the silicon oxide film described with reference to FIG. 8, and therefore, is omitted.

### Effects of First Embodiment

The effects of the first embodiment described above are as follows.

(A) Substrates of different types may be processed using a single substrate processing apparatus.

(B) The processing of one type of substrate does not have adverse effects on the other types of substrates.

### Second Embodiment

In the second embodiment, the width of the tweezers transferring the wafer 200L is smaller than the second distance n between the support mechanisms 311L and 311R in the horizontal direction. The other configurations of the second embodiment are the same as those of the first embodiment.

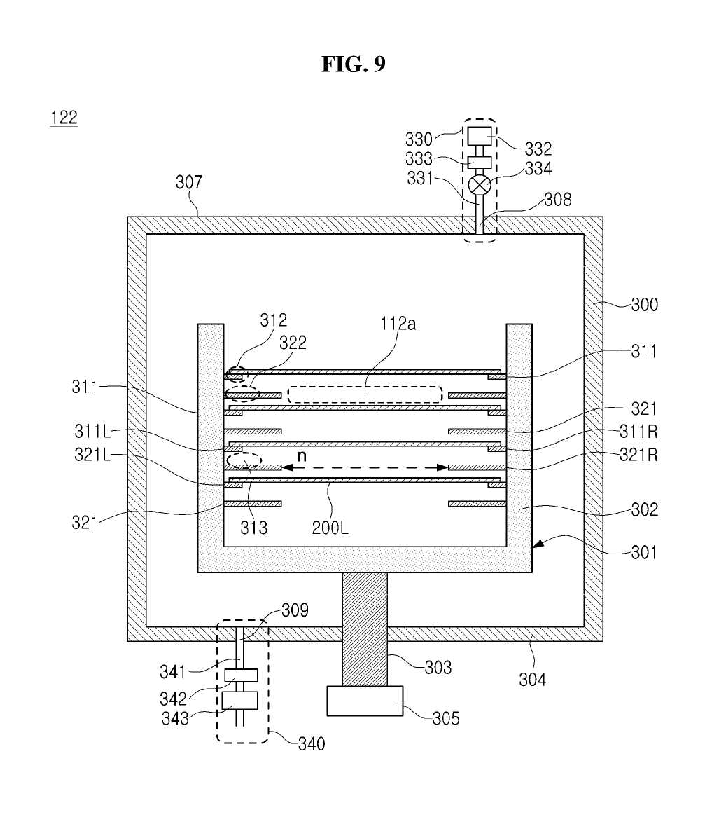

FIG. 9 is a diagram for showing the effect that can be obtained when the horizontal width of the first tweezers 112a is smaller than the second distance n between the support mechanisms 311L and 311R. An example will be described in case of the first tweezers 112a.

After the first tweezers 112a is positioned below the wafer 200L, the first tweezers 112a is lifted to pick up the wafer. In this case, the first tweezers 112a waits below the wafer 200L.

Thus, as shown in FIG. 11, in a structure wherein the support mechanisms 311L and 311R and the support mechanisms 321L and 321R are individually arranged in groups, a space is necessary between the support mechanisms 311L and 311R and between the support mechanisms 321L and 321R for the tweezers to wait. As a result, the height of the apparatus is increased.

On the other hand, according to the second embodiment, the support mechanisms 311L and 311R and the support mechanisms 321L and 321R are alternately arranged. in multiple stages in vertical direction. As shown in FIG. 9, when the wafer 200L is picked up, the space for the first tweezers 112a to wait is secured between the support mechanism 311R and the support mechanism 311L.

Therefore, according to the second embodiment, the height of the apparatus is less compared to that of the apparatus wherein the, support mechanism is individually arranged in groups as shown in FIG. 11.

### Other Embodiments

While the embodiments have been described above in detail, the above described technique is not limited thereto. The above-described technique may be modified in various ways without departing from the scope thereof.

While the film-funning process performed by the substrate processing apparatus is described based on the example of forming the silicon nitride film (SiN film) on the wafer 200 by alternately supplying HCD gas which is the first element-containing gas and O₂ gas which is the second element-containing gas, the above-described technique is not limited thereto. For example, the process gases used in the film-forming process are not limited to HCD gas and O₂ gas. The above-described technique may be applied to forming other thin films using gases other than HCD gas and O₂ gas. The above-described technique ma also be applied to a film-forming process performed by sequentially supplying three or more types of process gases. For example, the first element may include, for example, titanium (Ti), zirconium (Zr) or hafnium (Hf) instead of silicon (Si). The second element may include, for example, nitrogen (N) instead of oxygen (O). While the example of using the same first element gas for the processing of the wafer 200L and the processing of the wafer 200S is described, the above-described technique is not limited thereto. For example, completely different gases may be used for the processing of the wafer 200L and the processing of the wafer 200S.

In the embodiments described above, while the substrate processing apparatus performed the film-forming process, the above-described technique is not limited thereto. That is, the above-described technique may be applied to other film-forming processes and thin films formed thereby as well as the film-forming process exemplified in the embodiment. The above-described technique may be applied not only to the film-forming process but also to other substrate processings such as annealing, diffusion, oxidation, nitridation and lithography. The above-described technique may be applied to a substrate processing apparatus that performs substrate processing other than film-forming processes. That is, the above-described technique may be applied to a substrate processing apparatus such as an annealing apparatus, an etching apparatus, an oxidation apparatus, a nitriding apparatus, an exposure apparatus, a coating apparatus, a drying apparatus, a heating apparatus and a processing apparatus using plasma. The above-described technique may also be applied to combinations of the annealing apparatus, the etching apparatus, the oxidation apparatus, the nitriding apparatus, the exposure apparatus, the coating apparatus, the drying apparatus, the heating apparatus and the processing apparatus using plasma. Some elements of the above-described embodiments may be replaced with the elements of other embodiments, or the elements of other embodiments may be added to the above-described embodiments. Some elements of the above-described embodiments may be omitted.

According to the technique described herein, a substrate processing apparatus capable of processing substrates regardless of the types of substrates is provided.

1. A substrate processing apparatus, comprising:
a substrate retainer configured to support a substrate;
a loadlock chamber accommodating therein the substrate retainer;
a first transfer mechanism comprising first tweezers configured to transfer the substrate into the loadlock chamber or transfer the substrate out of the loadlock chamber through a first side of the loadlock chamber;
a second transfer mechanism comprising second tweezers configured to transfer the substrate into the loadlock chamber or transfer the substrate out of the loadlock chamber through a second side of the loadlock chamber; and
a reactor where the substrate is processed,
wherein the substrate retainer comprises: a sidewall; and a first support part and a second support part fixed to the sidewall and alternately arranged, the first support part comprising first support mechanisms spaced apart along a direction perpendicular to an entering direction of the first tweezers or the second tweezers, each of the first support mechanisms protruding from a surface of the sidewall and
having a first length from the surface of the sidewall to an end portion thereof, the second support part comprising second support mechanisms spaced apart along the direction perpendicular to the entering direction of the first tweezers or the second tweezers, each of the second support mechanisms protruding from the surface of the sidewall and having a second length from the surface of the sidewall to an end portion thereof, the second length being greater than the first length.

2. (canceled)

3. The substrate processing apparatus of claim 1, wherein the first support mechanisms are disposed on top.

4. The substrate processing apparatus of claim 3, wherein the first support mechanisms and the second support mechanisms are alternately arranged in multiple stages in vertical direction.

5. The substrate processing apparatus of claim 4, further comprising a controller configured to control the reactor and the first transfer mechanism to: place a substrate of first type on the first support part; read a first recipe when an instruction to load the substrate of first type into the reactor is received; and process the substrate of first type according to the first recipe when the substrate of first type is loaded; and to control the reactor and the second transfer mechanism to: place a substrate of second type on the second support part; read a second recipe when an instruction to load the substrate of second type into the reactor is received; and process the substrate of second type according to the second recipe when the substrate of second type is loaded.

6. The substrate processing apparatus of claim 3, further comprising a controller configured to control the reactor and the first transfer mechanism to: place a substrate of first type on the first support part; read a first recipe when an instruction to load the substrate of first type into the reactor is received; and process the substrate of first type according to the first recipe when the substrate of first type is loaded; and to control the reactor and the second transfer mechanism to: place a substrate of second type on the second support part; read a second recipe when an instruction to load the substrate of second type into the reactor is received; and process the substrate of second type according to the second recipe when the substrate of second type is loaded.

7. The substrate processing apparatus of claim 1, wherein the first support mechanisms and the second support mechanisms are alternately arranged in multiple stages in vertical direction.

8. The substrate processing apparatus of claim 7, further comprising a controller configured to control the reactor and the first transfer mechanism to: place a substrate of first type on the first support part; read a first recipe when an instruction to load the substrate of first type into the reactor is received; and process the substrate of first type according to the first recipe when the substrate of first type is loaded; and to control the reactor and the second transfer mechanism to: place a substrate of second type on the second support part; read a second recipe when an instruction to load the substrate of second type into the reactor is received; and process the substrate of second type according to the second recipe when the substrate of second type is loaded.

9. The substrate processing apparatus of claim 1, further comprising a controller configured to control the reactor and the first transfer mechanism to: place a substrate of first type on the first support part; read a first recipe when an instruction to load the substrate of first type into the reactor is received; and process the substrate of first type according to the first recipe when the substrate of first type is loaded; and to control the reactor and the second transfer mechanism to: place a substrate of second type on the second support part; read a second recipe when an instruction to load the substrate of second type into the reactor is received; and process the substrate of second type according to the second recipe when the substrate of second type is loaded.

10. (canceled)

11. (canceled)

12. (canceled)

13. (canceled)

14. (canceled)

15. (canceled)

16. (canceled)
